(19) United States
(12) Patent Application Publication
(10) Pub. No.: US 2025/0338759 A1
(43) Pub. Date: Oct. 30, 2025

(54) DISPLAY DEVICE AND ELECTRONIC DEVICE INCLUDING THE SAME

(71) Applicant: Samsung Display Co., Ltd., Yongin-Si (KR)

(72) Inventors: Gak Seok LEE, Yongin-si (KR); Do Hyuk KWON, Yongin-si (KR); Chan Su KIM, Yongin-si (KR); Keun Chan OH, Yongin-si (KR); Sang Hun LEE, Yongin-si (KR); In Ok KIM, Yongin-si (KR); Han Jun YU, Yongin-si (KR); Chang Soon JANG, Yongin-si (KR); Kyung Hwan JEON, Yongin-si (KR)

(21) Appl. No.: 18/966,129

(22) Filed: Dec. 3, 2024

(30) Foreign Application Priority Data
Apr. 29, 2024 (KR) 10-2024-0056813

(51) Int. Cl. H10K 59/80; H10K 59/38

(52) U.S. Cl. CPC H10K 59/877; H10K 59/38

(57) ABSTRACT

A display device includes a substrate including a first sub-pixel and a second sub-pixel, a light emitting structure on the substrate, a first light conversion pattern disposed in the first sub-pixel on the light emitting structure, a second light conversion pattern disposed in the second sub-pixel on the light emitting structure, and a dichroic layer on the second light conversion layer. The first light conversion pattern includes a light scattering particle, and the second light conversion pattern has an absence of the light scattering particle.

### CROSS-REFERENCE TO RELATED APPLICATION

The present application claims priority under 35 U.S.C. § 119(a) to Korean patent application No. 10-2024-0056813 filed on Apr. 29, 2024 in the Korean Intellectual Property Office, the entire disclosure of which is incorporated herein by reference.

### BACKGROUND

### 1. Technical Field

The present disclosure generally relates to a display device and an electronic device including the same.

### 2. Related Art

Recently, as interest in information displays is increased, research and development of display devices have been continuously conducted.

### SUMMARY

Embodiments provide a display device capable of decreasing the reflectivity of the display device and improving White Angular Dependency (WAD) characteristics.

In accordance with an aspect of the present disclosure, there is provided a display device including: a substrate including a first sub-pixel and a second sub-pixel; a light emitting structure on the substrate; a first light conversion pattern disposed in the first sub-pixel on the light emitting structure; a second light conversion pattern disposed in the second sub-pixel on the light emitting structure; and a dichroic layer on the second light conversion layer. The first light conversion pattern includes a light scattering particle, and the second light conversion pattern has an absence of the light scattering particle.

The display device may further include a low refractive layer on the first light conversion pattern and the second light conversion pattern.

The low refractive layer may be disposed between the second light conversion pattern and the dichroic layer.

The display device may further include: a first color filter on the first light conversion pattern; and a second color filter on the second light conversion pattern.

The dichroic layer may be disposed between the second light conversion pattern and the second color filter.

The second color filter may be disposed between the second light conversion pattern and the dichroic layer.

The first light conversion pattern may further include a first light conversion particle, and the second light conversion pattern may include a second light conversion particle.

The dichroic layer may not overlap with the first light conversion pattern.

The dichroic layer may overlap with the first light conversion pattern.

The substrate may further include a third sub-pixel. The display device may further include a light scattering pattern disposed in the third sub-pixel on the light emitting structure.

The light scattering pattern may include the light scattering particle.

The dichroic layer may not overlap with the light scattering pattern.

The dichroic layer may overlap with the light scattering pattern.

In accordance with another aspect of the present disclosure, there is provided a display device including: a substrate including a first sub-pixel and a second sub-pixel; a light emitting structure on the substrate; a first light conversion pattern disposed in the first sub-pixel on the light emitting structure; a second light conversion pattern disposed in the second sub-pixel on the light emitting structure; a first color filter on the first light conversion pattern; and a second color filter on the second light conversion pattern. The first light conversion pattern includes a light scattering particle, the second light conversion pattern has an absence of the light scattering particle, and the second color filter includes a dichroic dye.

The first light conversion pattern may further include a first light conversion particle, and the second light conversion pattern may include a second light conversion particle.

The substrate may further include a third sub-pixel. The display device may further include a light scattering pattern disposed in the third sub-pixel on the light emitting structure.

The light scattering pattern may include the light scattering particle.

The display device may further include a third color filter on the light scattering pattern.

The third color filter may include a dichroic dye.

The display device may further include a low refractive layer on the first light conversion pattern and the second light conversion pattern.

In accordance with an aspect of the present disclosure, there is provided an electronic device including: a processor to provide input image data; and a display device to display an image based on the input image data, the display device including sub-pixel areas, wherein the display device comprises a substrate including a first sub-pixel and a second sub-pixel; a light emitting structure on the substrate; a first light conversion pattern disposed in the first sub-pixel on the light emitting structure; a second light conversion pattern disposed in the second sub-pixel on the light emitting structure; and a dichroic layer on the second light conversion layer. The first light conversion pattern includes a light scattering particle, and the second light conversion pattern has an absence of the light scattering particle.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating an embodiment of a display device.

FIG. 2 is a block diagram illustrating an embodiment of any one of sub-pixels shown in FIG. 1.

FIG. 3 is a circuit diagram illustrating an embodiment of the sub-pixel shown in FIG. 2.

FIG. 4 is a plan view illustrating an embodiment of a display panel shown in FIG. 1.

FIG. 5 is a sectional view illustrating an embodiment taken along line I-I′ shown in FIG. 4.

FIG. 6 is a plan view illustrating an embodiment of any one of pixels shown in FIG. 4.

FIGS. 7, 8, 9, 10, 11, and 12 are sectional views illustrating an embodiment taken along line II-II′ shown in FIG. 6.

FIG. 13 is a sectional view illustrating an embodiment of a light emitting structure shown in FIGS. 7 to 12.

FIG. 14 is a sectional view illustrating an embodiment of the light emitting structure shown in FIGS. 7 to 12.

FIG. 15 is a plan view illustrating an embodiment of one of the pixels shown in FIG. 4.

FIG. 16 is a plan view illustrating an embodiment of one of the pixels shown in FIG. 4.

FIG. 17 is a block diagram illustrating an embodiment of a display system.

FIG. 18 is a perspective view illustrating an application example of the display system shown in FIG. 17.

FIG. 19 is a view illustrating a head-mounted display device shown in FIG. 18, which is worn by a user.

### DETAILED DESCRIPTION

Hereinafter, embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

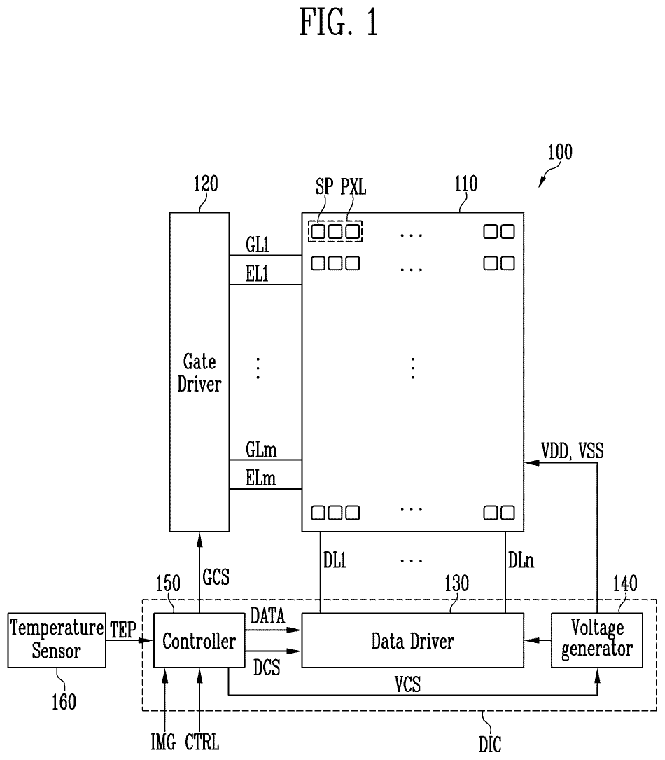

FIG. 1 is a block diagram illustrating an embodiment of a display device 100.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

Each of the sub-pixels SP may include at least one light emitting element configured to generate light. Accordingly, each of the sub-pixels SP may generate light of a specific color such as red, green, blue, cyan, magenta or yellow. Two or more sub-pixels among the sub-pixels SP may constitute one pixel PXL. For example, three sub-pixels SP may constitute one pixel PXL as shown in FIG. 1.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In an embodiment, the gate control signal GCS may include a start signal indicating a start of each frame, a horizontal synchronization signal for outputting gate signals in synchronization with timings at which data signals are applied, and the like.

In an embodiment, first to mth light emitting control lines EL1 to ELm connected to the sub-pixels SP in the row direction may be further provided. The gate driver 120 may include an emission control driver configured to control the first to mth emission control lines EL1 to ELm, and the emission control driver may operate under the control of the controller 150.

The gate driver 120 may be disposed at one side of the display panel 110. However, embodiments are not limited thereto. For example, the gate driver 120 may be divided into two or more drivers which are physically and/or logically divided, and these drivers may be disposed at one side of the display panel 110 and the other side of the display panel 110, which is opposite to the one side. As such, in accordance with embodiments, the gate driver 120 may be disposed in various forms at the periphery of the display panel 110.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In an embodiment, the data control signal DCS may include a source start pulse, a source shift clock, a source output enable signal, and the like.

The data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the data lines DL1 to DLm. Accordingly, corresponding sub-pixels SP may generate light corresponding to the data signals. Accordingly, an image may be displayed on the display panel 110.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from the outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the voltage level of the first power voltage VDD. In an embodiment, the first power voltage VDD or the second power voltage VSS may be provided by an external device of the display device 100.

Besides, the voltage generator 140 may generate various voltages. For example, the voltage generator 140 may generate an initialization voltage applied to the sub-pixels SP. For example, a predetermined reference voltage may be applied to the first to nth data lines DL1 to DLn in a sensing operation for sensing electrical characteristics of transistors and/or light emitting elements of the sub-pixels SP, and the voltage generator 140 may generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. In an embodiment, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In an embodiment, at least one of the data driver 130, the voltage generator 140, and the controller 150 may be provided as a component distinguished from the driver integrated circuit DIC.

The display device 100 may include at least one temperature sensor 160. The temperature sensor 160 may be configured to sense a temperature at the periphery thereof and generate temperature data TEP indicating the sensed temperature. In an embodiment, the temperature sensor 160 may be disposed to be adjacent to the display panel 110 and/or the driver integrated circuit DIC.

The controller 150 may control various operations of the display device 100 in response to the temperature data TEP. In an embodiment, the controller 150 may adjust the luminance of an image output from the display panel 100 in response to the temperature data TEP. For example, the controller 150 may control components such as the data driver 130 and/or the voltage generator 140, thereby adjusting data signals and the first and second power voltages VDD and VSS.

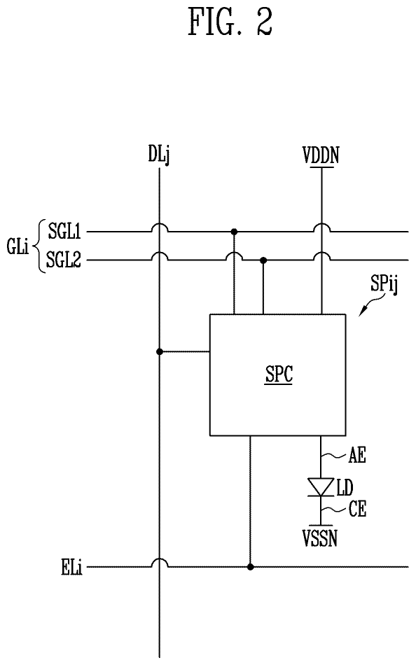

FIG. 2 is a block diagram illustrating an embodiment of any one of the sub-pixels shown in FIG. 1.

In FIG. 2, a sub-pixel SPij arranged on an ith row (i is an integer greater than or equal to 1 and smaller than or equal to m) and a jth column (j is an integer greater than or equal to 1 and smaller than or equal to n) among the sub-pixels SP shown in FIG. 1 may be exemplarily illustrated.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be a node transferring the first power voltage VDD shown in FIG. 1, and the second power voltage node VSSN may be a node transferring the second power voltage VSS shown in FIG. 1.

An anode electrode AE of the light emitting element LD may be connected to the first power voltage node VDDN through the sub-pixel circuit SPC, and a cathode electrode CE of the light emitting element LD may be connected to the second power voltage node VSSN. For example, the anode electrode AE of the light emitting element LD may be connected to the first power voltage node VDDN through one or more transistors included in the sub-pixel circuit SPC.

The sub-pixel circuit SPC may be connected to an ith gate line GLi among the first to mth gate lines GL1 to GLm shown in FIG. 1, an ith emission control line ELi among the first to mth emission control lines EL1 to ELm shown in FIG. 1, and a jth data line DLj among the first to nth data lines DL1 to DLn shown in FIG. 1. The sub-pixel circuit SPC may be configured to control the light emitting element LD according to signals received through these signal lines.

The sub-pixel circuit SPC may operate in response to a gate signal received through the ith gate line GLi. The ith gate line GLi may include one or more sub-gate lines. In an embodiment, as shown in FIG. 2, the ith gate line GLi may include first and second sub-gate lines SGL1 and SGL2. The sub-pixel circuit SPC may operate in response to gate signals received through the first and second sub-gate lines SGL1 and SGL2. As such, when the ith gate line GLi includes two or more sub-gate lines, the sub-pixel circuit SPC may operate in response to gate signals received through the corresponding sub-gate lines.

The sub-pixel circuit SPC may operate in response to an emission control signal received through the ith emission control line ELi. In an embodiment, the ith emission control line ELi may include one or more sub-emission control lines. When the ith emission control line ELi includes two or more sub-emission control lines, the sub-pixel circuit SPC may operate in response to emission control signals receives through the corresponding emission control lines.

The sub-pixel circuit SPC may receive a data signal through the jth data line DLj. The sub-pixel circuit SPC may store a voltage corresponding to the data signal in response to at least one of the gate signals received through the first and second sub-gate lines SGL1 and SGL2. The sub-pixel circuit SPC may control a current flowing from the first power voltage node VDDN to the second power voltage node VSSN through the light emitting element LD according to the stored voltage in response to the emission control signal received through the ith emission control line ELi. Accordingly, the light emitting element LD may generate light with a luminance corresponding to the data signal.

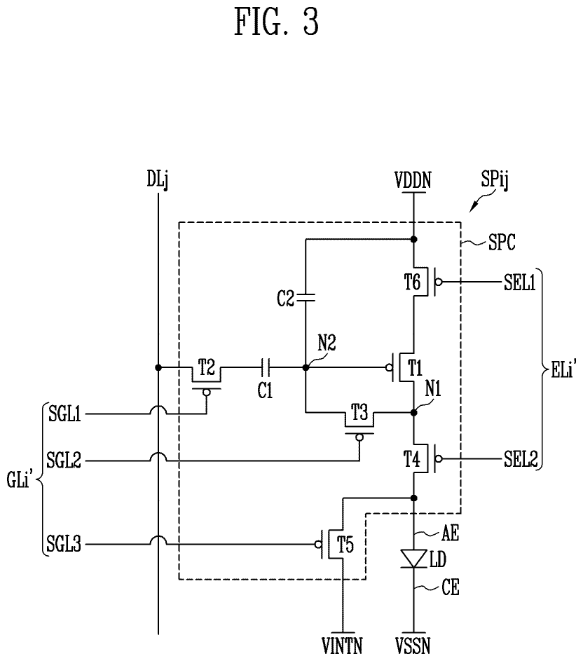

FIG. 3 is a circuit diagram illustrating an embodiment of the sub-pixel SPij shown in FIG. 2.

Referring to FIG. 3, the sub-pixel SPij may include a sub-pixel circuit SPC and a light emitting element LD.

The sub-pixel circuit SPC may be connected to an ith gate line GLi′, an ith emission control line ELi′, and a jth data line DLj. When comparing the ith gate line GLi′ with the ith gate line GLi shown in FIG. 2, the ith gate line GLi′ may further include a third sub-gate line SGL3. When comparing the ith emission control line ELi′ with the ith emission control line ELi shown in FIG. 2, the ith emission control line ELi′ may include a first sub-emission control line SEL1 and a second sub-emission control line SEL2.

The sub-pixel circuit SPC may include first to sixth transistors T1 to T6 and first and second capacitors C1 and C2.

The first transistor T1 may be connected between a first power voltage node VDDN and a first node N1. A gate of the first transistor T1 may be connected to a second node N2, and accordingly, the first transistor T1 may be turned on according to a voltage level of the second node N2. The first transistor T1 may be designated as a driving transistor.

The second transistor T2 may be connected between the jth data line DLj and the second node N2. A gate of the second transistor T2 may be connected to the first sub-gate line SGL1, and accordingly, the second transistor T2 may be turned on in response to a gate signal of the first sub-gate line SGL1. The second transistor T2 may be designated as a switching transistor.

The third transistor T3 may be connected between the first node N1 and the second node N2. A gate of the third transistor T3 may be connected to the second sub-gate line SGL2, and accordingly, the third transistor T3 may be turned on in response to a gate signal of the second sub-gate line SGL2.

The fourth transistor T4 may be connected between the first node N1 and an anode electrode AE of the light emitting element LD. A gate of the fourth transistor T4 may be connected to the second sub-emission control line SEL2, and accordingly, the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transfer an initialization voltage. In an embodiment, the initialization voltage may be provided by the voltage generator 140 shown in FIG. 1. In an embodiment, the initialization voltage may be provided by an external device of the display device 100. A gate of the fifth transistor T5 may be connected to the third sub-gate line SGL3, and accordingly, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and accordingly, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As such, the sub-pixel circuit SPC may include the first to sixth transistors T1 to T6 and the first and second capacitors C1 and C2. However, embodiments are not limited thereto. The sub-pixel circuit SPC may be implemented as any one of various types of circuits each including a plurality of transistors and one or more capacitors. For example, the sub-pixel circuit SPC may include two transistors and one capacitor. In accordance with embodiments of the sub-pixel circuit SPC, the number of sub-gate lines included in the ith gate line GLi′ and the number of sub-emission control lines included in the ith emission control line ELi′ may vary.

The first to sixth transistors T1 to T6 may be P-type transistors. Each of the first to sixth transistors T1 to T6 may be a Metal Oxide Silicon Field Effect Transistor (MOSEFT). However, embodiments are not limited thereto. For example, at least one of the first to sixth transistors T1 to T6 may be replaced with an N-type transistor.

In an embodiment, the first to sixth transistors T1 to T6 may include an amorphous silicon semiconductor, a monocrystalline silicon semiconductor, a polycrystalline silicon semiconductor, an oxide semiconductor, and the like.

The light emitting element LD may include the anode electrode AE, a cathode electrode CE, and a light emitting layer. The light emitting layer may be disposed between the anode electrode AE and the cathode electrode CE. After a data signal transferred through the jth data line DLj is reflected on a voltage of the second node N2, the fourth and sixth transistors T4 and T6 may be turned on when the emission control signals of the first and second sub-emission control lines SEL1 and SEL2 are enabled to a low level. The first transistor T1 may be turned on according to the voltage of the second node N2, and accordingly, a current may flow from the first power voltage node VDDN to a second power voltage node VSSN. The light emitting element LD may emit light according to an amount of the current flowing from the first power voltage node VDDN to the second power voltage node VSSN.

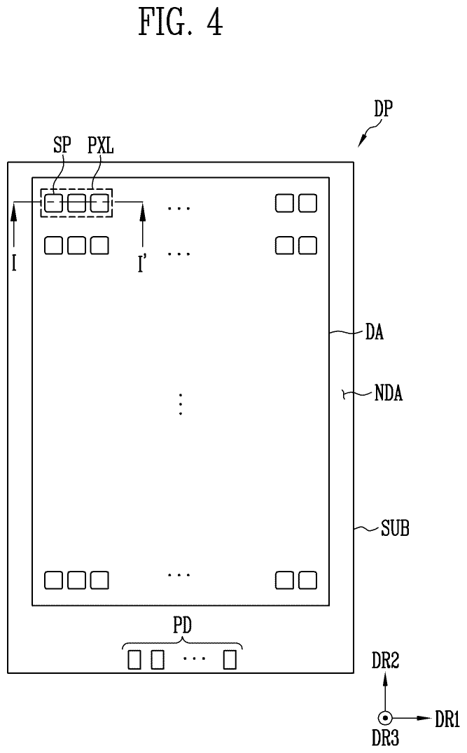

FIG. 4 is a plan view illustrating an embodiment of the display panel 110 shown in FIG. 1.

Referring to FIG. 4, a display panel DP may include a display area DA and a non-display area NDA. The display panel DP may display an image through the display area DA. The non-display area NDA may be disposed at the periphery of the display area DA.

The display panel DP may include a substrate SUB, sub-pixels SP, and pads PD.

When the display panel DP is used as a display screen of a Head Mounted Display (HMD), a Virtual Reality (VR) device, a Mixed Reality (MR) device, an Augmented Reality (AR) device, and the like, the display panel DP may be located very close to eyes of a user. The sub-pixels SP having a relatively high degree of integration may be required. In order to increase the degree of integration of the sub-pixels SP, the substrate SUB may be provided as a silicon substrate. The sub-pixels SP and/or the display panel DP may be formed on the substrate SUB as the silicon substrate. The display device 100 (see FIG. 1) including the display panel DP formed on the substrate SUB as the silicon substrate may be designated as an OLED on Silicon (OLEDoS) display device.

The sub-pixels SP may be disposed in the display area DA on the substrate SUB. The sub-pixels SP may be arranged in a matrix form along a first direction DR1 and a second direction DR2 intersecting the first direction DR1. However, embodiments are not limited thereto. For example, the sub-pixels SP may be arranged in a zigzag form along the first direction DR1 and the second direction DR2. For example, the sub-pixels SP may be disposed in a PENTILE™ form. The first direction DR1 may be a row direction, and the second direction DR2 may be a column direction.

Two or more sub-pixels among the sub-pixels SP may constitute one pixel PXL.

A component for controlling the sub-pixels SP may be disposed in the non-display area NDA on the substrate SUB. For example, lines connected to the sub-pixels SP, such as the first to mth gate lines GL1 to GLm and the first to nth data lines DL1 to DLn, which are shown in FIG. 1, may be disposed in the non-display area NDA.

At least one of the gate driver 120, the data driver 130, the voltage generator 140, the controller 150, and the temperature sensor 160, which are shown in FIG. 1, may be integrated in the non-display area NDA of the display panel DP. In an embodiment, the gate driver 120 shown in FIG. 1 is mounted on the display panel DP, and may be disposed in the non-display area NDA. In an embodiment, the gate driver 120 may be implemented as an integrated circuit distinguished from the display panel DP. In an embodiment, the temperature sensor 160 may be disposed in the non-display area NDA to sense a temperature of the display panel DP.

The pads PD may be disposed in the non-display area NDA on the substrate SUB. The pads PD may be electrically connected to the sub-pixels SP through the lines. For example, the pads PD may be connected to the sub-pixels SP through the first to nth data lines DL1 to DLn.

The pads PD may interface the display panel DP with other components of the display device 100 (see FIG. 1). In an embodiment, voltages and signals, which are necessary for operations of components included in the display panel DP, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

In an embodiment, a circuit board may be electrically connected to the pads PD, using a conductive adhesive member such as an anisotropic conductive film. The circuit board may be a Flexible Printed Circuit Board (FPCB) or a flexible film, which has a flexible material. The driver integrated circuit DIC may be mounted on the circuit board to be electrically connected to the pads PD.

In an embodiment, the display area DA may have various shapes. The display area DA may have a closed-loop shape including linear sides and/or curved sides. For example, the display area DA may have shapes such as a polygon, a circle, a semicircle, and an ellipse.

In an embodiment, the display panel DP may have a flat display surface. In an embodiment, the display panel DP may at least partially have a round display surface. In an embodiment, the display panel DP may be bendable, foldable or rollable. The display panel DP and/or the substrate SUB may include materials having flexibility.

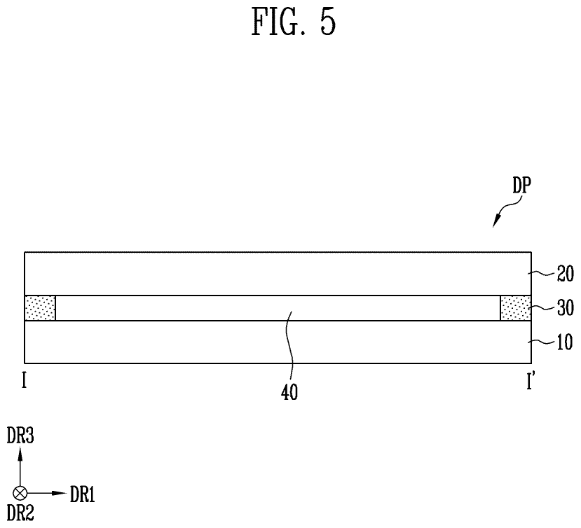

FIG. 5 is a sectional view illustrating an embodiment taken along line I-I′ shown in FIG. 4.

Referring to FIG. 5, the display panel DP may include a first substrate 10, a second substrate 20, and a sealing member 30. The sealing member 30 may couple the first substrate 10 and the second substrate 20 to each other. The first substrate 10 and the second substrate 20 may include a display area DA (see FIG. 4) and a non-display area NDA (see FIG. 4).

The first substrate 10 may include a plurality of sub-pixels SP (see FIG. 4) (or pixels PXL (see FIG. 4)), thereby displaying an image. The sub-pixels SP may be disposed in the display area DA of the first substrate 10. Each of the sub-pixels SP (or the pixels PXL) may include a light emitting element emitting light and a circuit element (or driving element) driving the light emitting element. For example, the light emitting element may be an organic light emitting diode, and the circuit element may be a transistor. However, the present disclosure is not limited thereto.

The second substrate 20 may include an optical layer which selectively converts light emitted from the light emitting element or allows light emitted from the light emitting element to be selectively transmitted therethrough. The optical layer may be disposed in, for example, the display area DA of the second substrate 20, and convert the wavelength of light emitted from the light emitting element of the first substrate 10 or allow light emitted from the light emitting element of the first substrate 10 to be transmitted therethrough as it is.

The first substrate 10 and the second substrate 20 may be coupled to each other by the sealing member 30. The sealing member 30 may be disposed in the non-display area NDA between the first substrate 10 and the second substrate 20. For example, the sealing member 30 is not disposed in the display area DA, but may be disposed in the non-display area NDA between the first substrate 10 and the second substrate 20 to surround the display area DA. For example, the sealing member 30 may have various planar shapes according to planar shapes of the first substrate 10 and/or the second substrate 20.

The sealing member 30 may include frit and the like. In some embodiments, the sealing member 30 may include a photocurable resin such as an epoxy acrylate-based resin, a polyester acrylate-based resin, a urethane acrylate-based resin, a polybutadiene acrylate-based resin, a silicon acrylate-based resin, or an alkyl acrylate-based resin. For example, laser light may be irradiated onto the sealing member applied between the first substrate 10 and the second substrate 20. The sealing member 30 may be cured by the laser light such that the first substrate 10 and the second substrate 20 are sealed. In some embodiments, the sealing member may control the flow of a monomer of an encapsulation layer included in the first substrate 10, thereby defining a position at which the monomer is formed.

A filling layer 40 may be disposed in the display area DA between the first substrate 10 and the second substrate 20. The filling layer 40 may function to buffer an external pressure or the like, which is applied to the display panel DP, but the present disclosure is not limited thereto. The filling layer 40 may maintain a gap between the first substrate 10 and the second substrate 20. The filling layer 40 may extend to the non-display area NDA between first substrate 10 and the second substrate 20 to meet (or be in contact with) the sealing member 30.

The filling layer 40 may include a material through which light can be transmitted. For example, the filling layer 40 may include an organic material such as a silicon-based resin, an epoxy-based resin, or an epoxy-acryl-based resin. Also, the filling layer 40 may include an appropriate material for refractive index matching.

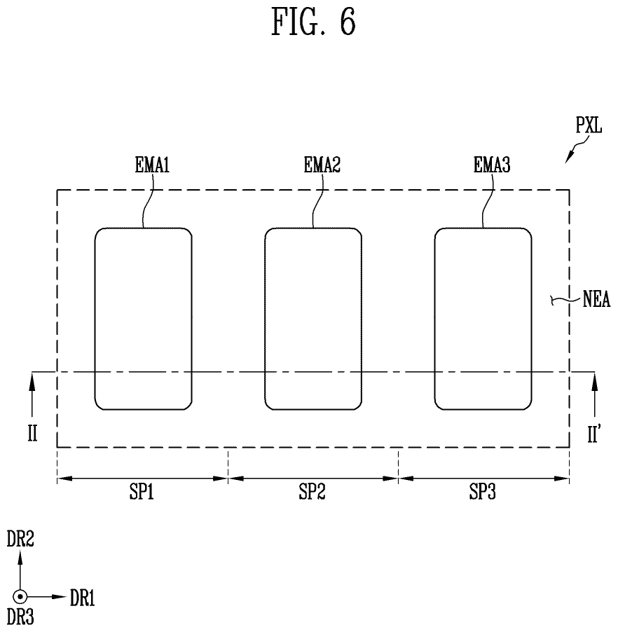

FIG. 6 is a plan view illustrating an embodiment of any one of the pixels shown in FIG. 4.

Referring to FIG. 6, the pixel PXL may include first to third sub-pixels SP1, SP2, and SP3 arranged in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

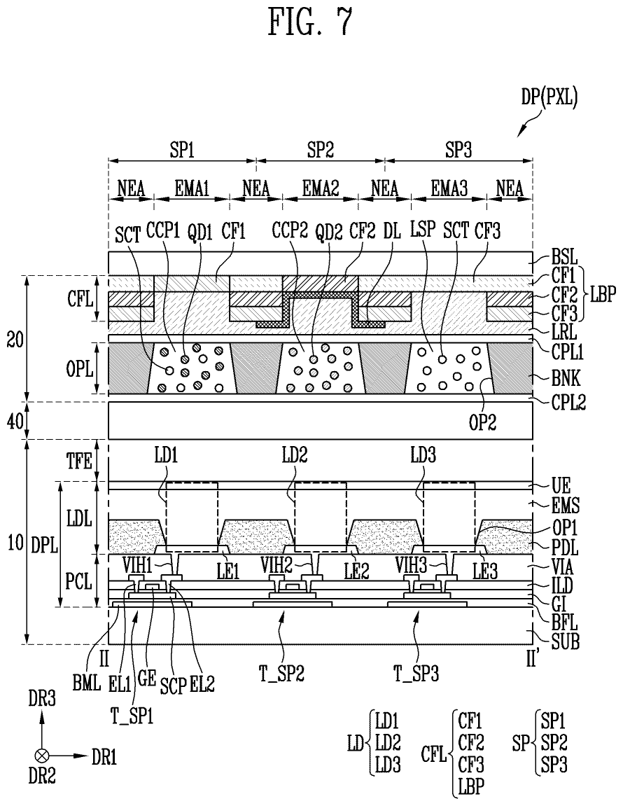

The first emission area EMA1 may be an area in which light is emitted from a portion of the light emitting structure EMS (see FIG. 7), which corresponds to the first sub-pixel SP1. The second emission area EMA2 may be an area in which light is emitted from a portion of the light emitting structure EMS, which corresponds to the second sub-pixel SP2. The third emission area EMA3 may be an area in which light is emitted from a portion of the light emitting structure EMS, which corresponds to the third sub-pixel SP3.

FIGS. 7 to 12 are sectional views illustrating an embodiment taken along line II-II′ shown in FIG. 6.

In FIGS. 7 to 12, for convenience of description, a sectional structure (or stacked structure) of the display panel DP is briefly illustrated based on the pixel PXL formed on the substrate SUB.

Referring to FIGS. 7 to 12, the pixel PXL may include at least one sub-pixel SP. In an example, the pixel PXL may include a first sub-pixel SP1, a second sub-pixel SP2, and a third sub-pixel SP3. In an embodiment, the first sub-pixel SP1 may be a red sub-pixel, the second sub-pixel SP2 may be a green sub-pixel, and the third sub-pixel SP3 may be a blue sub-pixel. However, the present is not limited thereto.

Each of the first to third sub-pixels SP1, SP2, and SP3 may include a first substrate 10 and a second substrate 20. A filling layer 40 may be disposed between the first substrate 10 and the second substrate 20.

The first substrate 10 may include the substrate SUB, a display element layer DPL, and/or an encapsulation layer TFE. The display element layer DPL may include a pixel circuit layer PCL and a light emitting element layer LDL.

The substrate SUB may include a transparent insulating material to allow light to be transmitted therethrough. The substrate SUB may be a rigid substrate or a flexible substrate.

The pixel circuit layer PCL and the light emitting element layer LDL may overlap with each other in a third direction DR3. At least one insulating layer may be disposed in the pixel circuit layer PCL. In an example, the insulating layer may include a buffer layer BFL, a gate insulating layer GI, an interlayer insulating layer ILD, and/or a via layer VIA, which are sequentially stacked on the substrate SUB along the third direction DR3. The insulating layer disposed in the pixel circuit layer PCL is not limited to the above-described embodiment, and another insulating layer may be added.

The buffer layer BFL may be entirely disposed on the substrate SUB. The buffer layer BFL may prevent an impurity from being diffused into circuit elements (e.g., driving elements), e.g., transistors, constituting a pixel circuit SPC. The buffer layer BFL may be an inorganic insulating layer including an inorganic material (or substance). The buffer layer BFL may include at least one of silicon nitride (SiNₓ), silicon oxide (SiOₓ), silicon oxynitride (SiOₓN_{y}), and aluminum oxide (AlOₓ). The buffer layer BFL may be provided as a single layer, but be provided as a multi-layer including at least two layers. When the buffer layer BFL is provided as the multi-layer, the layers may be formed of the same material or be formed of different materials. The buffer layer BFL may be omitted according to a material of the substrate SUB, a process condition, and the like.

The gate insulating layer GI may be entirely disposed on the buffer layer BFL. The gate insulating layer GI may include the same material as the above-described buffer layer BFL, or include at least one material appropriate (or selected) from the materials mentioned (or exemplified) as the material constituting the buffer layer BFL. In an example, the gate insulating layer GI may be an inorganic insulting layer including an inorganic material.

The interlayer insulating layer ILD may be entirely provided and/or formed on the gate insulating layer GI. The interlayer insulating layer ILD may include the same material as the buffer layer BFL, or include at least one material appropriate (or selected) from the materials mentioned (or exemplified) as the material constituting the buffer layer BFL.

The via layer VIA may be entirely provided and/or formed on the interlayer insulating layer ILD. The via layer VIA may be an inorganic insulating layer including an inorganic material or an organic insulating layer including an organic material (or substance). The inorganic insulating layer may include, for example, at least one of silicon oxide (SiOₓ), silicon nitride (SiNₓ), silicon oxynitride (SiOₓN_{y}), and aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin. In an embodiment, the via layer VIA may be an organic insulating layer including an organic material.

The via layer VIA may be partially opened to include a via hole. A pixel circuit SPC and a light emitting element LD of each sub-pixel SP may be electrically connected to each other through the via hole.

Circuit elements (or driving elements) of each of the first to third sub-pixels SP1, SP2, and SP3 may be disposed in the pixel circuit layer PCL. In an example, a transistor T_SP1 of the first sub-pixel SP1, a transistor T_SP2 of the second sub-pixel SP2, and a transistor T_SP3 of the third sub-pixel SP3 may be disposed in the pixel circuit layer PCL. The transistor T_SP1 of the first sub-pixel SP1 may be one of transistors included in a pixel circuit SPC of the first sub-pixel SP1, the transistor T_SP2 of the second sub-pixel SP2 may be one of transistors included in a pixel circuit SPC of the second sub-pixel SP2, and the transistor T_SP3 of the third sub-pixel SP3 may be one of transistors included in a pixel circuit SPC of the third sub-pixel SP3. In FIGS. 7 to 12, for clear and brief description, one of transistors of each sub-pixel SP is illustrated, and the other circuit elements are omitted.

The transistor T_SP1 of the first sub-pixel SP1 may include a semiconductor pattern SCP, a gate electrode GE, a first terminal EL1, and/or a second terminal EL2.

The gate electrode GE may be disposed on the gate insulating layer GI to be covered by the interlayer insulating layer ILD. In an example, the gate electrode GE may be a gate conductive layer located between the gate insulating layer GI and the interlayer insulating layer

ILD. The gate electrode GE may overlap with a portion of the semiconductor pattern SCP. In an example, the gate electrode GE may overlap with an active layer of the semiconductor pattern SCP.

The semiconductor pattern SCP may be provided and/or formed on the buffer layer BFL. The semiconductor pattern SCP may be a semiconductor layer made of poly-silicon, amorphous silicon, an oxide semiconductor, or the like. The semiconductor pattern SCP may include the active pattern, a first contact region, and a second contact region. The active pattern, the first contact region, and the second contact region may be configured with a semiconductor layer undoped or doped with an impurity. In an example, the first contact region and the second contact region may be configured with a semiconductor layer doped with the impurity, and the active pattern may be configured with a semiconductor layer undoped with the impurity.

The active pattern of the semiconductor pattern SCP is a region overlapping with the gate electrode GE, and may be a channel region. The first contact region of the semiconductor pattern SCP may be in contact with one end of the active pattern. Also, the first contact region may be electrically connected to the first terminal EL1. The second contact region of the semiconductor pattern SCP may be in contact with the other end of the active pattern. Also, the second contact region may be electrically connected to the second terminal EL2.

The first terminal EL1 may be provided and/or formed on the interlayer insulating layer ILD. In an example, the first terminal EL1 may be configured as a source-drain conductive layer formed between the interlayer insulating layer ILD and the via layer VIA. The first terminal EL1 may be in contact with the first contact region of the semiconductor pattern SCP through a contact hole penetrating the gate insulating layer GI and the interlayer insulating layer ILD.

The second terminal EL2 may be provided and/or formed on the interlayer insulating layer ILD, and be disposed to be spaced apart from the first terminal EL1. The second terminal EL2 may be configured as a source-drain conductive layer formed between the interlayer insulating layer ILD and the via layer VIA. The second terminal EL2 may be in contact with the second contact region of the semiconductor pattern SCP through another contact hole penetrating the gate insulating layer GI and the interlayer insulating layer ILD.

A bottom metal layer BML may be disposed under the transistor T_SP1 of the above-described first sub-pixel SP1.

The bottom metal layer BML may be a first conductive layer located between the substrate SUB and the buffer layer BFL. Although not directly illustrated in the drawings, the bottom metal layer BML is electrically connected to the transistor T_SP1 of the first sub-pixel SP1, to extend the driving range of a predetermined voltage supplied to the gate electrode GE.

As the gate electrode GE, the first terminal EL1, and the second terminal LE2 are electrically connected to other circuit elements and/or lines, the transistor T_SP1 of the first sub-pixel SP1 may be provided as one of the transistors constituting the pixel circuit SPC of the first sub-pixel SP1.

Each of the transistor T_SP2 of the second sub-pixel SP2 and the transistor T_SP3 of the third sub-pixel SP3 may be configured substantially identical to the transistor T_SP1 of the first sub-pixel SP1.

As described above, the pixel circuit layer PCL may include circuit elements of each of the first to third sub-pixels SP1, SP2, and SP3.

The light emitting element layer LDL may be disposed on the pixel circuit layer PCL. The light emitting element layer LDL may include a first lower electrode LE1, a second lower electrode LE2, a third lower electrode LE3, a pixel defining layer PDL, a light emitting structure EMS, and/or an upper electrode UE.

On the pixel circuit layer PCL (or the via layer VIA), the first to third lower electrodes LE1, LE2, and LE3 may be disposed in the first to third sub-pixels SP1, SP2, and SP3, respectively. In an example, the first lower electrode LE1 may be disposed on the via layer VIA of the first sub-pixel SP1, the second lower electrode LE2 may be disposed on the via layer VIA of the second sub-pixel SP2, and the third lower electrode LE3 may be disposed on the via layer VIA of the third sub-pixel SP3.

Each of the first to third lower electrodes LE1, LE2, and LE3 may be electrically connected to a circuit element disposed in the pixel circuit layer PCL through a via hole penetrating the via layer VIA. In an example, the first lower electrode LE1 may be electrically connected to the transistor T_SP1 of the first sub-pixel SP1 through a first via hole VIH1 penetrating the via layer VIA, the second lower electrode LE2 may be electrically connected to the transistor T_SP2 of the second sub-pixel SP2 through a second via hole VIH2 penetrating the via layer VIA, and the third lower electrode LE3 may be electrically connected to the transistor T_SP3 of the third sub-pixel SP3 through a third via layer VIH3 penetrating the via layer VIA.

In an embodiment, each of the first to third lower electrodes LE1, LE2, and LE3 may be an anode electrode. Each of the first to third lower electrodes LE1, LE2, and LE3 may have a shape similar to a shape of each of the first to third emission areas EMA1, EMA2, and EMA3 shown in FIG. 6 on a plane. Each of the first to third lower electrodes LE1, LE2, and LE3 may be electrically connected to a corresponding pixel circuit SPC to be supplied with a driving current. The first to third lower electrodes LE1, LE2, and LE3 may include an opaque conductive material capable of reflecting light, but the present disclosure is not limited thereto. In some embodiments, the first to third lower electrodes LE1, LE2, and LE3 may include a transparent conductive material.

The pixel defining layer PDL may be located over the first to third lower electrodes LE1, LE2, and LE3. The pixel defining layer PDL may include a first opening (or openings) OP1 exposing each of a portion of the first lower electrode LE1, a portion of the second lower electrode LE2, and a portion of the third lower electrode LE3. The pixel defining layer PDL may be a structure defining (or partitioning) an emission area of each of the first to third sub-pixels SP1, SP2, and SP3. In an example, the pixel defining layer PDL may define the first emission area EMA1 of the first sub-pixel SP1, the second emission area EMA2 of the second sub-pixel SP2, and the third emission area EMA3 of the third sub-pixel SP3.

The pixel defining layer PDL may be configured with an organic insulating layer including an organic material. The organic material may include acrylic resin, epoxy resin, phenolic resin, polyamide resin, polyimide resin, and the like. In some embodiments, the pixel defining layer PDL may include a light absorption material or have a light absorber coated thereon, to absorb light introduced from the outside. For example, the pixel defining layer PDL may include a carbon-based black pigment. However, the present disclosure is not limited thereto.

The pixel defining layer PDL may protrude in the third direction DR3 from the via layer VIA.

The light emitting structure EMS may be disposed on the first to third lower electrodes LE1, LE2, and LE3 exposed by the first openings OP1 of the pixel defining layer PDL. The light emitting structure EMS may include a light emitting layer configured to generate light, an electron transport unit configured to transport electrons, a hole transport unit configured to transport holes, and the like. However, the present disclosure is not limited thereto.

The light emitting structure EMS may be disposed on the top of the pixel defining layer PDL, and fill the first openings OP1 of the pixel defining layer PDL. The light emitting structure EMS may be formed through a process such as vacuum deposition or inkjet printing.

The upper electrode UE may be disposed on the light emitting structure EMS. In an embodiment, the upper electrode UE may be a cathode electrode. The upper electrode UE may be a common layer commonly provided in the first to third sub-pixels SP1, SP2, and SP3. The upper electrode UE may be provided in a plate shape throughout the entire display device DA. The upper electrode UE may serve as a half mirror which allows light emitted from the light emitting structure EMS to be partially transmitted therethrough or be partially reflected therefrom.

The upper electrode UE may be a thin metal layer having a thickness to a degree to which the upper electrode UE can allow light emitted from the light emitting structure EMS to be transmitted therethrough. The upper electrode UE may be formed of a metal material to having a relatively thin thickness or be formed of a transparent conductive material. In an embodiment, the upper electrode UE may include at least one of various transparent conductive materials including indium tin oxide, indium zinc oxide, indium tin zinc oxide, aluminum zinc oxide, gallium zinc oxide, zinc tin oxide, and gallium tin oxide. In an embodiment, the upper electrode UE may include at least one of magnesium, silver, and mixtures thereof. However, the material of the upper electrode UE is not limited to the above-described embodiment.

The first lower electrode LE1, a portion of the light emitting structure EMS, which overlaps with the first lower electrode LE1, and a portion of the upper electrode UE, which overlaps with the first lower electrode LE1, may constitute a first light emitting element LD1. The second lower electrode LE2, a portion of the light emitting structure EMS, which overlaps with the second lower electrode LE2, and a portion of the upper electrode UE, which overlaps with the second lower electrode LE2, may constitute a second light emitting element LD2. The third lower electrode LE3, a portion of the light emitting structure EMS, which overlaps with the third lower electrode LE3, and a portion of the upper electrode UE, which overlaps with the third lower electrode LE3, may constitute a third light emitting element LD3.

The encapsulation layer TFE may be disposed on the upper electrode UE. The encapsulation layer TFE may cover the display element layer DPL. The encapsulation layer TFE may be configured to prevent oxygen and/or moisture from infiltrating into the light emitting element layer LDL. In an embodiment, the encapsulation layer TFE may include a structure in which at least one inorganic layer and at least one organic layer are alternately stacked. For example, the inorganic layer may include silicon nitride, silicon oxide, silicon oxynitride, or the like. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene. However, the materials of the organic layer and the inorganic layer of the encapsulation layer TFE are not limited thereto.

The second substrate 20 may be located above the first substrate 10 including the above-described components. The second substrate 20 may face the first substrate 10 in the third direction DR3.

The second substrate 20 may include a base layer BSL, a color filter layer CFL, a dichroic layer DL, a low refractive layer LRL, a first capping layer CPL1, an optical layer OPL, and/or a second capping layer CPL2.

The base layer BSL may be a rigid substrate or a flexible substrate, and the material or property of the base layer BSL is not particularly limited. The base layer BSL may be configured with the same material as the substrate SUB or be configured with a material different from the material of the substrate SUB.

The color filter layer CFL may be disposed on one surface of the base layer BSL. The one surface of the base layer BSL may mean a surface facing the first substrate 10. The color filter layer CFL may include a first color filter CF1, a second color filter CF2, a third color filter CF3, and/or a light blocking pattern LBP. The first color filter CF1 may be disposed on the one surface of the base layer BSL to correspond to the first emission area EMA1 of the first sub-pixel SP1, the second color filter CF2 may be disposed on the one surface of the base layer BSL to correspond to the second emission area EMA2 of the second sub-pixel SP2, and the third color filter CF3 may be disposed on the one surface of the base layer BSL to correspond to the third emission area EMA3 of the third sub-pixel SP3.

The first color filter CF1, the second color filter CF2, and the third color filter CF3 may be disposed in the non-emission area NEA while overlapping with each other, to be used as the light blocking pattern LBP which blocks light interference between adjacent sub-pixels SP. The light blocking pattern LBP may include the first color filter CF1, the second color filter CF2, and/or the third color filter CF3, which are sequentially stacked on the one surface of the base layer BSL. In an example, the first color filter CF1 may be a red color filter, the second color filter CF2 may be a green color filter, and the third color filter CF3 may be a blue color filter. However, the present disclosure is not limited thereto.

The low refractive layer LRL may be disposed on the color filter layer CFL in a direction facing the first substrate 10. The low refractive layer LRL (or refractive index layer) may change a path of light emitted from the optical layer OPL in a front direction (or an image display direction of the display panel DP), using a refractive index difference in the display area DA, thereby improving the luminance of light output to the front.

The first capping layer CPL1 may be disposed on the low refractive layer LRL. The first capping layer CPL1 may be located on the color filter layer CFL. The first capping layer CPL1 may cover the color filter layer CFL, thereby protecting the color filter layer CFL. For example, the first capping layer CPL1 may be configured with an inorganic layer (or inorganic insulating layer) including an inorganic material.

The optical layer OPL may be disposed on the first capping layer CPL1 in the direction facing the first substrate 10. The optical layer OPL may include a bank BNK, a first light conversion pattern CCP1, a second light conversion pattern CCP2, and/or a light scattering pattern LSP.

The bank BNK may include at least one light blocking material and/or at least one reflective material to allow light emitted from each of the first light conversion pattern CCP1, the second light conversion pattern CCP2, and the light scattering pattern LSP to advance in the image display direction of the display panel DP, thereby improving the light output efficiency of each sub-pixel SP. In some embodiments, the bank BNK may prevent a light leakage defect in which light is leaked between adjacent sub-pixels SP. In some embodiments, the bank BNK may include a transparent material (or substance). The transparent material may include, for example, a polyamide-based resin, a polyimide-based resin, and the like, but the present disclosure is not limited thereto. In other embodiments, a reflective material layer may be separately provided and/or formed on the bank BNK so as to improve the efficiency of light emitted from each sub-pixel SP.

The bank BNK may include a second opening (or openings) OP2 exposing a portion of the first capping layer CPL1 in each of the first to third sub-pixels SP1, SP2, and SP3. For example, the bank BNK may include a second opening OP2 exposing a portion of the first capping layer CPL1 in the first sub-pixel SP1, a second opening OP2 exposing a portion of the first capping layer CPL1 in the second sub-pixel SP2, and a second opening OP2 exposing a portion of the first capping layer CPL1 in the third sub-pixel SP3. The second opening OP2 of the bank BNK may correspond to an emission area of each sub-pixel SP. In an example, the second opening OP2 of the bank BNK in the first sub-pixel SP1 may correspond to the first emission area EMA1, the second opening OP2 of the bank BNK in the second sub-pixel SP2 may correspond to the second emission area EMA2, and the second opening OP2 of the bank BNK in the third sub-pixel SP3 may correspond to the third emission area EMA3.

The bank BNK may be a structure which defines positions of the first light conversion pattern CCP1, the second light conversion pattern CCP2, and the light scattering pattern LSP.

The first light conversion pattern CCP1 may be located in the second opening OP2 of the bank BNK of the first sub-pixel SP1 to correspond to the first light emitting element LD1. The first light conversion pattern CCP1 may include first light conversion particles QD1 dispersed in a predetermined matrix material such as base resin. For example, the first light conversion particles QD1 may be red quantum dots which emit red light by absorbing incident blue light and shifting a wavelength of the blue light according to energy transition. The first sub-pixel SP1 may be a red sub-pixel. The first light conversion pattern CCP1 may be disposed in at least the first emission area EMA1.

In an embodiment, the first light conversion pattern CCP1 may include light scattering particles SCT. The first light conversion pattern CCP1 may include light scattering particles such as silica, but the material constituting the light scattering particles SCT is not limited thereto. As such, when the first light conversion pattern CCP1 includes the light scattering particles SCT, the efficiency of the first light conversion pattern CCP1 can be improved.

The second light conversion pattern CCP2 may be located in the second opening OP2 of the bank BNK of the second sub-pixel SP2 to correspond to the second light emitting element LD2. The second light conversion pattern CCP2 may include second light conversion particles QD2 dispersed in a predetermined matrix material such as base resin. For example, the second light conversion particles QD2 may be green quantum dots which emit green light by absorbing incident blue light and shifting a wavelength of the blue light according to energy transition. The second sub-pixel SP2 may be a green sub-pixel. The second light conversion pattern CCP2 may be disposed in at least the second emission area EMA2.

In an embodiment, the second light conversion pattern CCP2 may include no light scattering particle. Light scattering reflection in the second light conversion pattern CCP2 can be prevented, and thus the reflectivity of the display panel DP can be decreased.

The light scattering pattern LSP may be located in the second opening OP2 of the bank BNK of the third sub-pixel SP3 to correspond to the third light emitting element LD3. The light scattering pattern LSP may include second light scattering particles SCT dispersed in a predetermined matrix material such as base resin. The light scattering pattern LSP may include light scattering particles SCT such as silica, but the material constituting the light scattering particles SCT is not limited thereto. In some embodiments, the light scattering particles SCT may be omitted such that the light scattering pattern LSP configured with a transparent polymer is provided. For example, the light scattering pattern LSP may allow incident blue light to be transmitted in the image display direction therethrough. The third sub-pixel SP3 may be a blue sub-pixel. The light scattering pattern LSP may be disposed in at least the third emission area EMA3.

In an embodiment, the dichroic layer DL may be disposed above the second light conversion pattern CCP2. The dichroic layer DL may include a dichroic dye. As described above, when the second light conversion pattern CCP2 includes no light scattering particle, the reflectivity of the display panel DP can be decreased, but color shift at a side viewing angle, i.e., White Angular Dependency (WAD) characteristics may be deteriorated due to an increase in side luminance ratio. Accordingly, the dichroic layer DL is disposed above the second light conversion pattern CCP2 including no light scattering particle, so that the increase in side luminance ratio can be compensated by the anisotropy of the dichroic dye. Thus, the WAD characteristics can be improved.

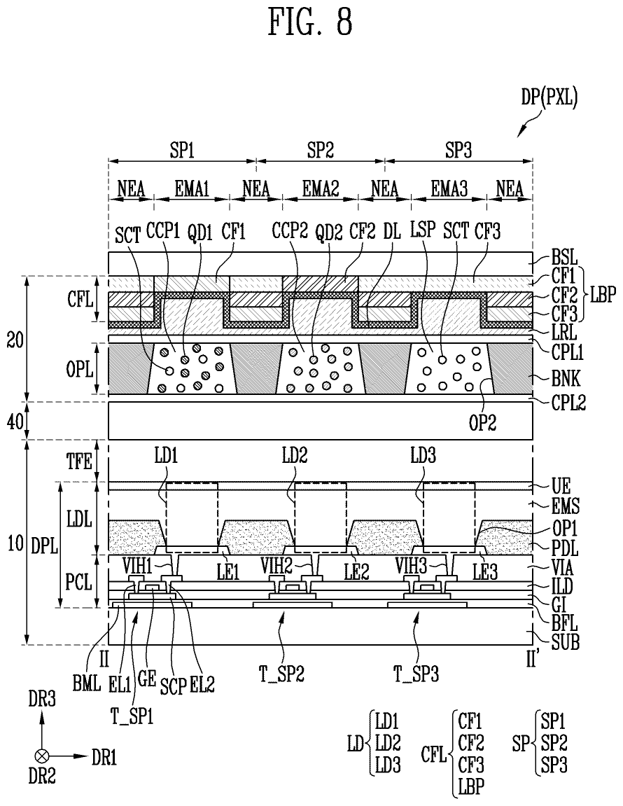

Referring to FIGS. 7 and 8, each dichroic layer DL may be disposed between the optical layer OPL and the color filter layer CFL. The low refractive layer LRL may be disposed between the optical layer OPL and the dichroic layer DL.

As shown in FIG. 7, a dichroic layer DL may be partially disposed in the second sub-pixel SP2. The dichroic layer DL may be partially disposed in the second emission area EMA2. The dichroic layer DL may be partially disposed between the second light conversion pattern CCP2 and the second color filter CF2. The dichroic layer DL may be partially disposed between the low refractive layer LRL and the second color filter CF2. The dichroic layer DL may not overlap with the first sub-pixel SP1 and the third sub-pixel SP3 in the third direction DR3. The dichroic layer DL may not overlap with the first emission area EMA1 and the third emission area EMA3 in the third direction DR3. The dichroic layer DL may not overlap with the first light conversion pattern CCP1 and the light scattering pattern LSP in the third direction DR3.

In an embodiment, as shown in FIG. 8, a dichroic layer DL may be entirely disposed in the first to third sub-pixels SP1, SP2, and SP3. As such, when the dichroic layer DL is entirely formed on the base layer BSL, the number of masks can be decreased, thereby simplifying manufacturing processes. The dichroic layer DL may overlap with the first to third sub-pixels SP1, SP2, and SP3 in the third direction DR3. The dichroic layer DL may overlap with the first to third emission areas EMA1, EMA2, and EMA3 in the third direction DR3. The dichroic layer DL may overlap with the first light conversion pattern CCP1, the second light conversion pattern CCP2, and the light scattering pattern LSP in the third direction DR3.

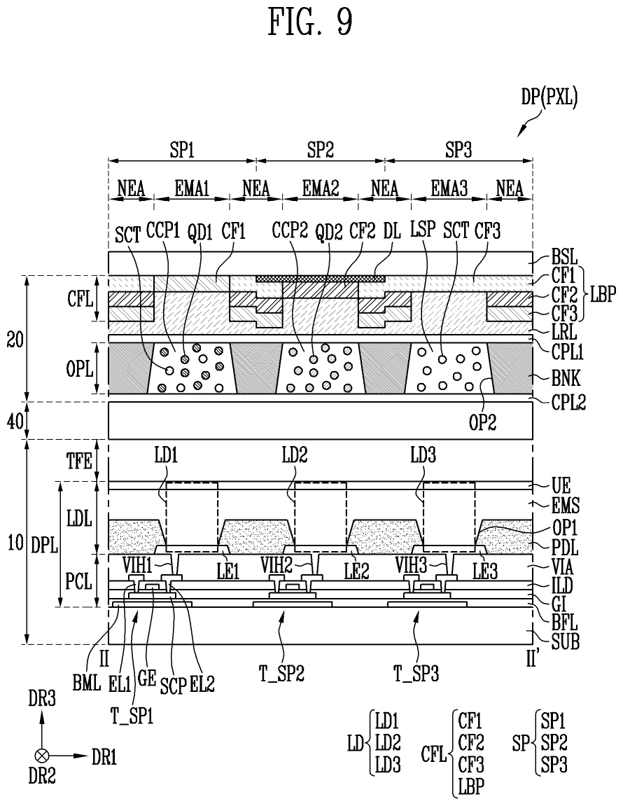

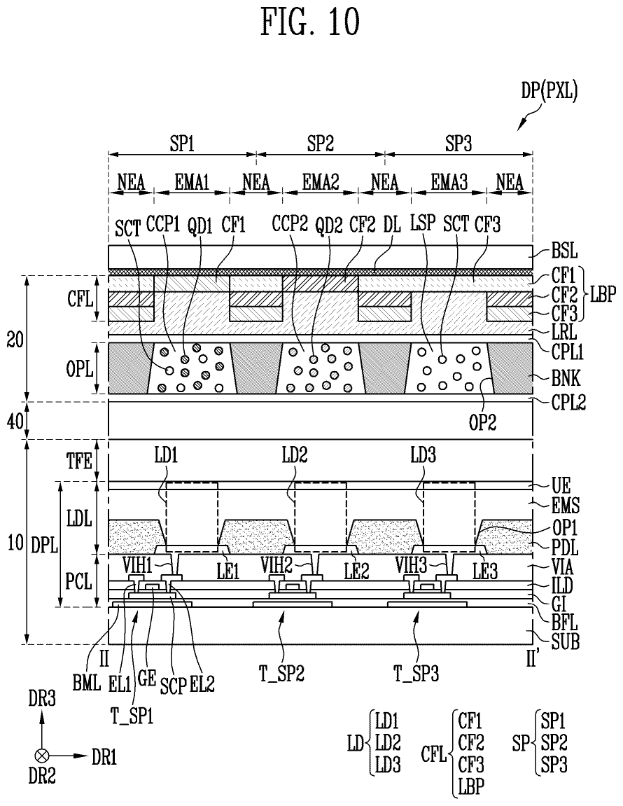

Referring to FIGS. 9 and 10, each dichroic layer DL may be disposed between the color filter layer CFL and the base layer BSL. The color filter layer CFL may be disposed between the optical layer OPL and the dichroic layer DL. The color filter layer CFL may be disposed between the low refractive layer LRL and the dichroic layer DL.

As shown in FIG. 9, the dichroic layer DL may be partially disposed in the second sub-pixel SP2. The dichroic layer DL may be partially disposed in the second emission area EMA2. The dichroic layer DL may be partially disposed between the second color filter CF2 and the base layer BSL. The second color filter CF2 may be disposed between the second light conversion pattern CCP2 and the dichroic layer DL. The dichroic layer DL may not overlap with the first sub-pixel SP1 and the third sub-pixel SP3 in the third direction DR3. The dichroic layer DL may not overlap with the first emission area EMA1 and the third emission area EMA3 in the third direction DR3. The dichroic layer DL may not overlap with the first light conversion pattern CCP1 and the light scattering pattern LSP in the third direction DR3.

In an embodiment, as shown in FIG. 10, the dichroic layer DL may be entirely disposed in the first to third sub-pixels SP1, SP2, and SP3. As such, when the dichroic layer DL is entirely formed on the base layer BSL, the number of masks can be decreased, thereby simplifying manufacturing processes. The dichroic layer DL may overlap with the first to third sub-pixels SP1, SP2, and SP3 in the third direction DR3. The dichroic layer DL may overlap with the first to third emission areas EMA1, EMA2, and EMA3 in the third direction DR3. The dichroic layer DL may overlap with the first light conversion pattern CCP1, the second light conversion pattern CCP2, and the light scattering pattern LSP in the third direction DR3.

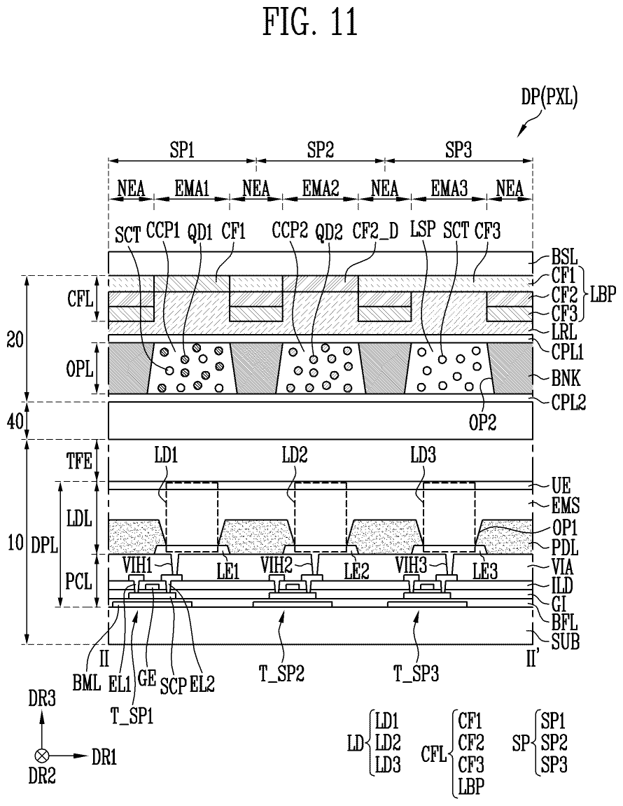

In some embodiments, as shown in FIG. 11, the dichroic layer may be omitted, and a second color filter CF2_D may include a dichroic dye. As described above, when the second light conversion pattern CCP2 includes no light scattering particle, the reflectivity of the display panel DP may be decreased, but WAD characteristics at a side viewing angle may be deteriorated due to an increase in side luminance ratio. Accordingly, the second color filter CF2_D including the dichroic dye is disposed on the second light conversion pattern CCP2 including no light scattering particle, so that the increased in side luminance ratio can be compensated by front/side absorption anisotropy of the dichroic dye, thereby improving the WAD characteristics.

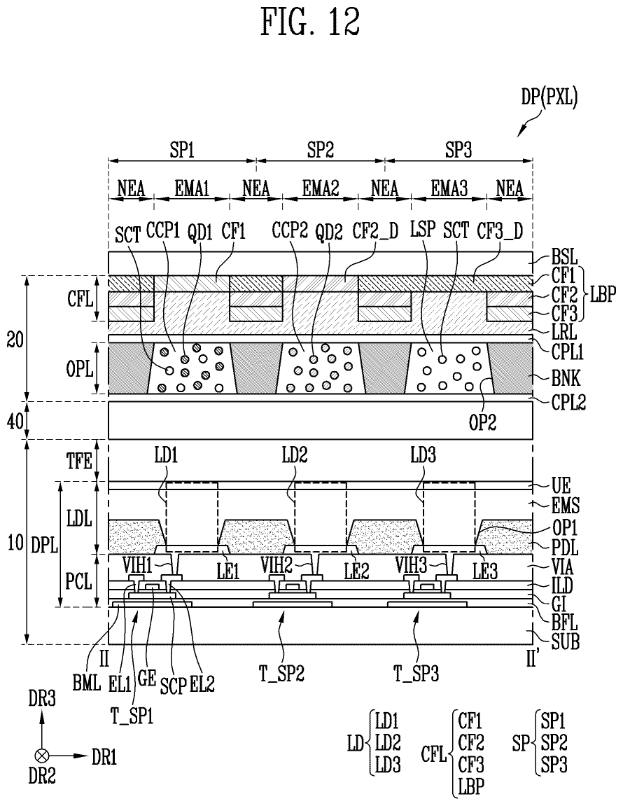

In an embodiment, as shown in FIG. 12, the dichroic layer may be omitted, and a second color filter CF2_D and a third color filter CF3_D may include a dichroic dye. As such, when the second color filter CF2_D and the third color filter CF3_D include the dichroic dye, the increased in side luminance ratio can be compensated by front/side absorption anisotropy of the dichroic dye, thereby improving the WAD characteristics, which has been described above.

In the direction facing the first substrate 10, the second capping layer CPL2 may be disposed on the optical layer OPL. The second capping layer CPL2 may be configured with an inorganic layer (or inorganic insulating layer) including an inorganic material. For example, the second capping layer CPL2 may include at least one of silicon nitride (SiNₓ), silicon oxide (SiOₓ), silicon oxynitride (SiOₓN_{y}), and aluminum oxide (AlOₓ), but the present disclosure is not limited thereto. In some embodiments, the second capping layer CPL2 may be configured with an organic insulating layer including an organic material. The second capping layer CPL2 may be located on the optical layer OPL, to protect the optical layer OPL from external moisture, oxygen, and the like, thereby improving the reliability of the optical layer OPL.

The filling layer 40 may be disposed in the display area DA between the second substrate 20 and the first substrate 10, which have the above-described components. For example, the filling layer 40 may be disposed between the encapsulation layer TFE of the first substrate 10 and the second capping layer CPL2 of the second substrate 20. The filling layer 40 may maintain a gap between the first substrate 10 and the second substrate 20.

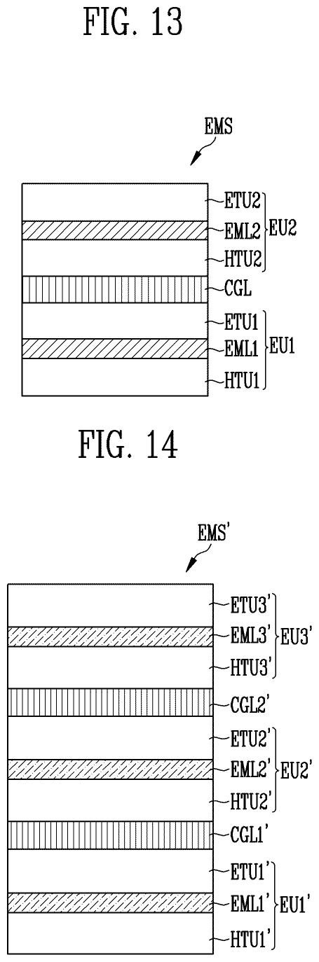

FIG. 13 is a sectional view illustrating an embodiment of the light emitting structure EMS shown in FIGS. 7 to 12.

Referring to FIG. 13, the light emitting structure EMS may have a tandem structure in which first and second light emitting units EU1 and EU2 are stacked. The light emitting structure EMS may be configured substantially identically in each of the first to third light emitting elements LD1, LD2, and LD3 shown in FIGS. 7 to 12.

Each of the first and second light emitting units EU1 and EU2 may include at least one light emitting layer generating light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer. Each of the first and second hole transport units HTU1 and HTU2 may further include a hole buffer layer, an electron blocking layer, and the like, if necessary. The first and second hole transport units HTU1 and HTU2 may have the same configuration or have different configurations.

Each of the first and second electron transport units ETU1 and ETU2 may include at least one of an electron injection layer and an electron transport layer. Each of the first and second electron transport units ETU1 and ETU2 may further include an electron buffer layer, a hole blocking layer, and the like, if necessary. The first and second electron transport units ETU1 and ETU2 may have the same configuration or have different configurations.

A connection layer, which may be provided in the form of a charge generation layer CGL, may be disposed between the first light emitting unit EU1 and the second light emitting unit EU2 to connect the first light emitting unit EU1 and the second light emitting unit EU2 to each other. In an embodiment, the charge generation layer CGL may have a stacked structure of a p-dopant layer and an n-dopant layer. For example, the p-dopant layer may include a p-type dopant such as HAT-CN, TCNQ or NDP-9, and the n-dopant layer may include an alkali metal, an alkali earth metal, a lanthanide-based metal, or any combination thereof. However, embodiments are not limited thereto.

In an embodiment, the first light emitting layer EML1 and the second light emitting layer EML2 may generate lights of different colors. Lights respectively emitted from the first light emitting layer EML1 and the second light emitting layer EML2 may be mixed together, to be viewed as white light. For example, the first light emitting layer EML1 may generate light of a blue color, and the second light emitting layer EML2 may generate light of a yellow color. In an embodiment, the second light emitting layer EML2 may include a structure in which a first sub-light emitting layer configured to generate light of a red color and a second sub-light emitting layer configured to generate light of a green color are stacked. The light of the red color and the light of the green color may be mixed together to provide the light of the yellow color. An intermediate layer configured to perform a function of transporting holes and/or a function of blocking transportation of electrodes may be further disposed between the first and second sub-light emitting layers. In an embodiment, the first light emitting layer EML1 and the second light emitting layer EML2 may generate light of the same color.

The light emitting structure EMS may be formed through a process such as vacuum deposition or inkjet printing, but embodiments are not limited thereto.

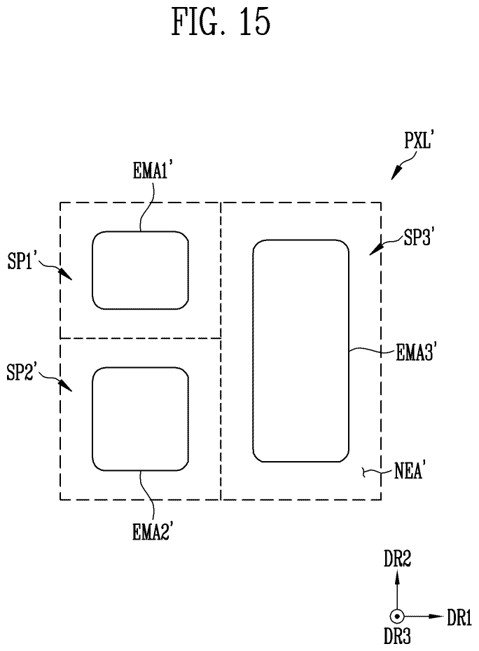

FIG. 14 is a sectional view illustrating an embodiment of the light emitting structure shown in FIGS. 7 to 12.

Referring to FIG. 14, a light emitting structure EMS′ may a tandem structure in which first to third light emitting units EU1′, EU2′, and EU3′ are stacked. The light emitting structure EMS′ may be configured substantially identically in each of the first to third light emitting elements LD1, LD2, and LD3 shown in FIGS. 7 to 12.

Each of the first to third light emitting units EU1′, EU2′, and EU3′ may include a light emitting layer generating light according to an applied current. The first light emitting unit EU1′ may include a first light emitting layer EML1′, a first electron transport unit ETU1' and a first hole transport unit HTU1′. The first light emitting layer EML1′ may be disposed between the first electron transport unit ETU1' and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′, HTU2′, and HTU3′ may include at least one of a hole injection layer and a hole transport layer, and further include a hole buffer layer, and an electron blocking layer, and the like, if necessary. The first to third hole transport units HTU1′, HTU2′, and HTU3′ may have the same configuration or have different configurations.

Each of the first to third electron transport units ETU1′, ETU2′, and ETU3′ may include at least one of an electron injection layer and an electron transport layer, and further include an electron buffer layer, a hole blocking layer, and the like, if necessary. The first to third electron transport units ETU1′, ETU2′, and ETU3′ may have the same configuration or have different configurations.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In an embodiment, the first to third light emitting layers EML1′, EML2′, and EML3′ may generate lights of different colors. Lights respectively emitted from the first to third light emitting layers EML1′, EML2′, and EML3′ may be mixed together, to be viewed as white light. For example, the first light emitting layer EML1′ may generate light of a blue color, the second light emitting layer EML2′ may generate light of a green color, and the third light emitting layer EML3′ may generate light of a red color. In an embodiment, at least two light emitting layers among the first to third light emitting layers EML1′, EML2′, and EML3′ may generate light of the same color.

In some embodiments, unlike as shown in FIGS. 13 and 14, the light emitting structure EMS may include one light emitting unit in each of the first to third light emitting elements LD1, LD2, and LD3. The light emitting unit included in each of the first to third light emitting elements LD1, LD2, and LD3 may be configured to emit lights of different colors. For example, the light emitting unit of the first light emitting element LD1 may emit light of a red color, the light emitting unit of the second light emitting element LD2 may emit light of a green color, and the light emitting unit of the third light emitting element LD3 may emit light of a blue color. Light emitting units of the first to third sub-pixels SP1, SP2, and SP3 may be separated from each other. At least some of the color filters CF1, CF2, and CF3 may be omitted.

FIG. 15 is a plan view illustrating an embodiment of one of the pixels shown in FIG. 4.

Referring to FIG. 15, a pixel PXL′ may include first to third sub-pixels SP1′, SP2′, and SP3′.

The first sub-pixel SP1′ may include a first emission area EMA1' and a non-emission area NEA′ at the periphery of the first emission area EMA1′. The second sub-pixel SP2′ may include a second emission area EMA2′ and the non-emission area NEA′ at the periphery of the second emission area EMA2′. The third sub-pixel SP3′ may include a third emission area EMA3′ and the non-emission area NEA′ at the periphery of the third emission area EMA3′.

The first sub-pixel SP1′ and the second sub-pixel SP2′ may be arranged in the second direction DR2. The third sub-pixel SP3′ may be disposed in the first direction DR1 with respect to each of the first and second sub-pixels SP1′ and SP2′.

The second sub-pixel SP2′ may have an area greater than an area of the first sub-pixel SP1′, and the third sub-pixel SP3′ may have an area greater than the area of the second sub-pixel SP2′. Accordingly, the second emission area EMA2′ may have an area greater than an area of the first emission area EMA1′, and the third emission area EMA3′ may have an area greater than the area of the second emission area EMA2′. However, embodiments are not limited thereto. For example, the first and second sub-pixels SP1′ and SP2′ may substantially have the same area, and the third sub-pixel SP3′ may have an area greater than the area of each of the first and second sub-pixels SP1′ and SP2′. As such, the areas of the first to third sub-pixels SP1′, SP2′, and SP3′ may be variously modified in some embodiments.

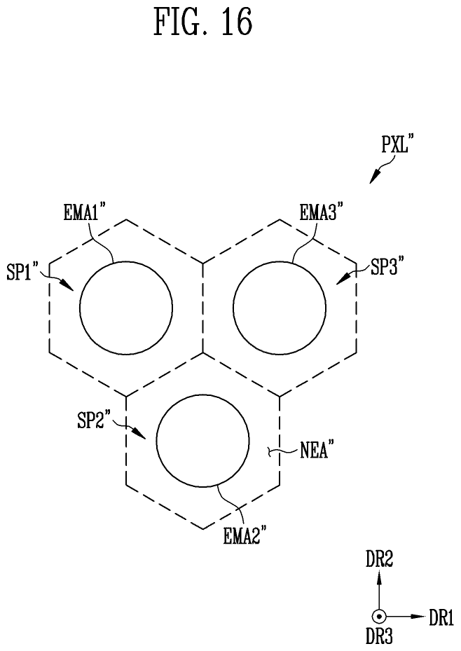

FIG. 16 is a plan view illustrating an embodiment of one of the pixels shown in FIG. 4.

Referring to FIG. 16, a pixel PXL″ may include first to thirds sub-pixels SP1″, SP2″, and SP3″. The first sub-pixel SP1″ may include a first emission area EMA1″ and a non-emission area NEA″ at the periphery of the first emission area EMA1″. The second sub-pixel SP2″ may include a second emission area EMA2″ and the non-emission area NEA″ at the periphery of the second emission area EMA2″. The third sub-pixel SP3″ may include a third emission area EMA3″ and the non-emission area NEA″ at the periphery of the third emission area EMA3″.

The first to third sub-pixels SP1″, SP2″, and SP3″ may have polygonal shapes when viewed in the third direction DR3. For example, the shapes of the first to third sub-pixels SP1″, SP2″, and SP3″ may be hexagonal shapes.

The first to third emission areas EMA1″, EMA2″, and EMA3″ may have circular shapes when viewed in the third direction DR3. However, embodiments are not limited thereto. For example, each of the first to third emission areas EMA1″, EMA2″, and EMA3″ may have a polygonal shape.

The first and third sub-pixels SP1″ and SP3″ may be arranged in the first direction DR1. The second sub-pixel SP2″ may be disposed in a direction (or diagonal direction) inclined by an acute angle, based on the second direction DR2, with respect to the first sub-pixel SP1″.

The arrangements of the sub-pixels, which are shown in FIGS. 6, 15, and 16, are merely illustrative, and embodiments are not limited thereto. Each pixel may include two or more sub-pixels, and the sub-pixels may be arranged in various manners. Each of the sub-pixels may have various shapes, and an emission area EMA of the sub-pixel may have various shapes.

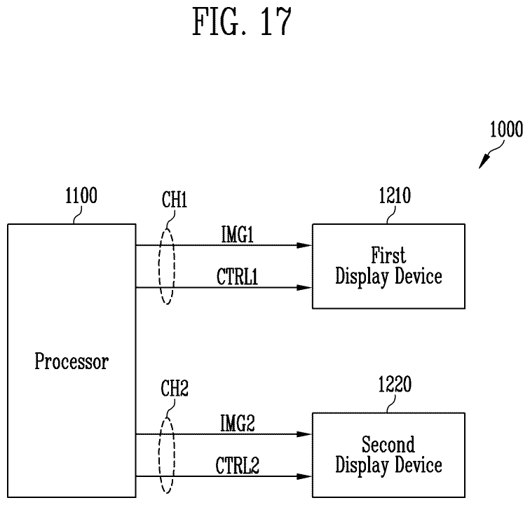

FIG. 17 is a block diagram illustrating an embodiment of a display system 1000.

Referring to FIG. 17, the display system 1000 may include a processor 1100 and one or more display devices 1210 and 1220.

The processor 1100 may perform various tasks and various calculations. In an embodiment, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

In FIG. 17, it is illustrated that the display system 1000 includes first and second display devices 1210 and 1220. The processor 1100 may be connected to the first display device 1210 through a first channel CH1, and be connected to the second display device 1220 through a second channel CH2.

Through the first channel CH1, the processor 1210 may transmit first image data IMG1 and a first control signal CTRL1 to the first display device 1210. The first display device 1210 may display an image, based on the first image data IMG1 and the first control signal CTRL1. The first display device 1210 may be configured identically to the display device 100 described with reference to FIG. 1. The first image data IMG1 and the first control signal CTRL1 may be respectively provided as the input image data IMG and the control signal CTRL, which are shown in FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device 100 described with reference to FIG. 1. The second image data IMG2 and the second control signal CTRL2 may be respectively provided as the image data IMG and the control signal CTRL, which are shown in FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

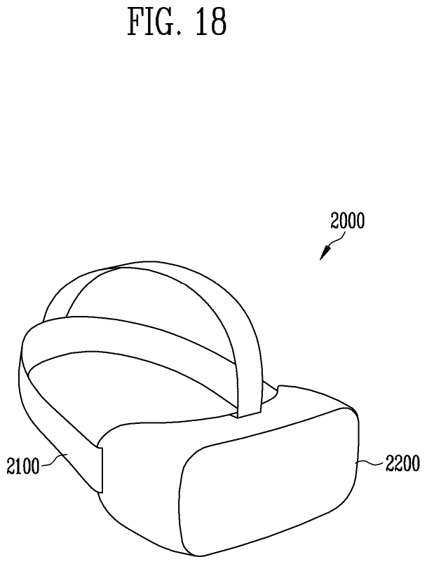

FIG. 18 is a perspective view illustrating an application example of the display system 1000 shown in FIG. 17.

Referring to FIG. 18, the display system 1000 shown in FIG. 17 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounting band 2100 may be implemented in the form of a glasses frame, a helmet or the like.

The display device accommodating case 2200 may accommodate the first and second display devices 1210 and 1220 shown in FIG. 17. The display device accommodating case 2200 may further accommodate the processor 1100 shown in FIG. 17.

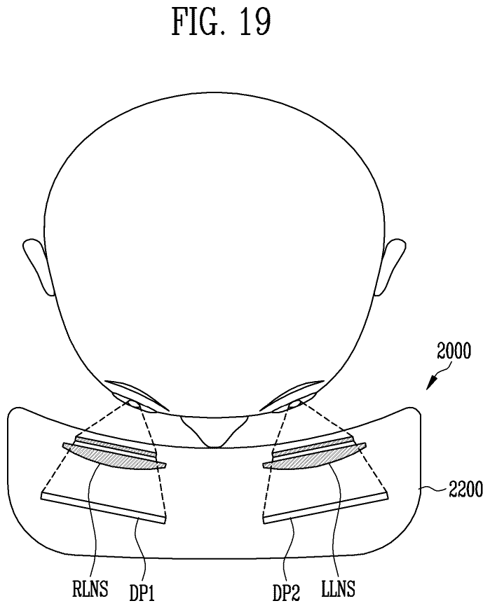

FIG. 19 is a view illustrating a head-mounted display device 2000 shown in FIG. 18, which is worn by a user.

Referring to FIG. 19, a first display panel DP1 of the first display device 1210 and a second display panel DP2 of the second display device 1220 may be disposed in the head mounted display device 2000. The head mounted display device 2000 may further include one or more lenses LLNS and RLNS.

In the display device accommodating case 2200, the right-eye lens RLNS may be disposed between the first display panel DP1 and a right eye of the user. In the display device accommodating case 2200, the left-eye lens LLNS may be disposed between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

In an embodiment, each of the right-eye lens RLNS and the left-eye lens LLNS may include an optical lens having a pancake-shaped section. In an embodiment, each of the right-eye lens RLNS and the left-eye lens LLNS may include a multi-channel lens including sub-areas having different optical characteristics. Each display panel may output images respectively corresponding to the sub-areas of the multi-channel lens, and the output images may be viewed by the user while respectively passing through corresponding sub-areas.

In accordance with the above-described embodiment, the dichroic layer DL or the second color filter CF2_D including a dichroic dye is disposed on the second light conversion pattern CCP2 including no light scattering particle, so that the reflectivity of the display device can be decreased and the WAD characteristics can be improved.

In accordance with the present disclosure, a second color filter including a dichroic layer or a dichroic dye is disposed on a second light conversion pattern including no light scattering particle, so that the reflectivity of the display device can be decreased and WAD characteristics can be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a substrate including a first sub-pixel and a second sub-pixel;
a light emitting structure on the substrate;
a first light conversion pattern disposed in the first sub-pixel on the light emitting structure;
a second light conversion pattern disposed in the second sub-pixel on the light emitting structure; and
a dichroic layer on the second light conversion layer,
wherein the first light conversion pattern includes a light scattering particle, and
the second light conversion pattern has an absence of the light scattering particle.

2. The display device of claim 1, further comprising a low refractive layer on the first light conversion pattern and the second light conversion pattern.

3. The display device of claim 2, wherein the low refractive layer is disposed between the second light conversion pattern and the dichroic layer.

4. The display device of claim 1, further comprising:
a first color filter on the first light conversion pattern; and
a second color filter on the second light conversion pattern.

5. The display device of claim 4, wherein the dichroic layer is disposed between the second light conversion pattern and the second color filter.

6. The display device of claim 4, wherein the second color filter is disposed between the second light conversion pattern and the dichroic layer.

7. The display device of claim 1, wherein the first light conversion pattern further includes a first light conversion particle, and
the second light conversion pattern includes a second light conversion particle.

8. The display device of claim 1, wherein the dichroic layer does not overlap with the first light conversion pattern.

9. The display device of claim 1, wherein the dichroic layer overlaps with the first light conversion pattern.

10. The display device of claim 1, wherein the substrate further includes a third sub-pixel, and
wherein the display device further comprises a light scattering pattern disposed in the third sub-pixel on the light emitting structure.

11. The display device of claim 10, wherein the light scattering pattern includes the light scattering particle.

12. The display device of claim 10, wherein the dichroic layer does not overlap with the light scattering pattern.

13. The display device of claim 10, wherein the dichroic layer overlaps with the light scattering pattern.

14. A display device comprising:
a substrate including a first sub-pixel and a second sub-pixel;
a light emitting structure on the substrate;
a first light conversion pattern disposed in the first sub-pixel on the light emitting structure;
a second light conversion pattern disposed in the second sub-pixel on the light emitting structure;
a first color filter on the first light conversion pattern; and
a second color filter on the second light conversion pattern,
wherein the first light conversion pattern includes a light scattering particle, and
the second light conversion pattern has an absence of the light scattering particle, and
wherein the second color filter includes a dichroic dye.

15. The display device of claim 14, wherein the first light conversion pattern further includes a first light conversion particle, and
the second light conversion pattern includes a second light conversion particle.

16. The display device of claim 14, wherein the substrate further includes a third sub-pixel, and
wherein the display device further comprises a light scattering pattern disposed in the third sub-pixel on the light emitting structure.

17. The display device of claim 16, wherein the light scattering pattern includes the light scattering particle.

18. The display device of claim 16, further comprising a third color filter on the light scattering pattern.

19. The display device of claim 18, wherein the third color filter includes a dichroic dye.

20. The display device of claim 14, further comprising a low refractive layer on the first light conversion pattern and the second light conversion pattern.

21. An electronic device comprising:
a processor to provide input image data; and
a display device to display an image based on the input image data, the display device including sub-pixel areas,
wherein the display device comprises:
a substrate including a first sub-pixel and a second sub-pixel;
a light emitting structure on the substrate;
a first light conversion pattern disposed in the first sub-pixel on the light emitting structure;
a second light conversion pattern disposed in the second sub-pixel on the light emitting structure; and
a dichroic layer on the second light conversion layer,
wherein the first light conversion pattern includes a light scattering particle, and
the second light conversion pattern has an absence of the light scattering particle.
